(19) United States
(12) Patent Application Publication
(10) Pub. No.: US 2026/0231577 A1
(43) Pub. Date: Aug. 6, 2026

(54) LIGHT EMITTING MODULE AND APPARATUS HAVING THE SAME

(71) Applicant: SEOUL VIOSYS CO., LTD., Ansan-si (KR)

(72) Inventors: Jina LEE, Ansan-si (KR); Changyoun KIM, Ansan-si (KR)

(73) Assignee: SEOUL VIOSYS CO., LTD., Ansan-si (KR)

(21) Appl. No.: 19/529,319

(22) Filed: Feb. 4, 2026

Related U.S. Application Data
(60) Provisional application No. 63/754,100, filed on Feb. 5, 2025.
(60) Provisional application No. 63/757,903, filed on Feb. 13, 2025.

(51) Int. Cl. H10H 29/34; H10H 29/49

(52) U.S. Cl. CPC H10H 29/34; H10H 29/49

(57) ABSTRACT

A light emitting module including a plurality of light emitting devices and a light emitting apparatus including the same. The light emitting module according to the present invention includes a substrate and a plurality of light emitting devices disposed on the substrate.

### CROSS-REFERENCE TO RELATED APPLICATIONS

The present application claims the benefit of priority to U.S. Provisional Application No. 63/754,100, filed Feb. 5, 2025, and U.S. Provisional Application No. 63/757,903, filed Feb. 13, 2025, the entire contents of which are incorporated herein by reference.

### FIELD

The present invention relates to a light emitting module and a light emitting apparatus including the same, and more specifically, to a light emitting module including a plurality of light emitting devices and a light emitting apparatus including the same.

### BACKGROUND

A light emitting diode (LED), as one of the light sources, is being widely used recently. The light emitting diode uses characteristics of compound semiconductors to convert electrical signals into forms of light, such as infrared, visible light, and ultraviolet light.

As the light efficiency of the light emitting diode increases, the light emitting device is being applied to various fields including display apparatuses, lighting equipment, vehicle lamps, or others.

Recently, smart televisions, VR (Virtual Reality), and AR (Augmented Reality) use light emitting diodes to display images. Meanwhile, as the demand for high-quality displays increases, the demand for low power consumption and fast response speed is also increasing.

In particular, a display apparatus in the form of LEDs disposed on a transparent substrate or a flexible substrate is also being actively developed.

### SUMMARY

An embodiment of the present invention may provide a light emitting module and a light emitting apparatus including the same, which can secure sufficient transparency.

An embodiment of the present invention may provide a light emitting module and a light emitting apparatus including the same, which have a high color reproduction rate using red, green, and blue light emitting devices.

An embodiment of the present invention may provide a light emitting module and a light emitting apparatus including the same, with improved driving reliability by reducing heat generation of a plurality of light emitting devices.

An embodiment of the present invention may provide a light emitting module and a light emitting apparatus including the same, in which structural stability can be improved even in a flexible structure.

In addition, an embodiment of the present invention may provide a light emitting module and a light emitting apparatus including the same, which can prevent a light emitting device from falling off, or prevent solder for mounting the light emitting device from being damaged when a substrate having flexibility is bent.

An embodiment of the present invention may provide a light emitting module and a light emitting apparatus including the same, with improved reliability in a flexible structure.

An embodiment of the present invention may provide a light emitting module and a light emitting apparatus including the same, which can prevent a short circuit in a flexible structure.

A light emitting module according to an embodiment of the present invention includes a substrate and a plurality of light emitting devices disposed on the substrate, wherein an interval between the plurality of light emitting devices may be 50 μm or more.

In one embodiment, the substrate may be a light-transmitting substrate.

In one embodiment, the light emitting module may further include a plurality of IC drivers disposed on the substrate for driving the plurality of light emitting devices.

In one embodiment, the interval between the plurality of light emitting devices may be 10 times or more of a side length of one of the light emitting devices.

In one embodiment, an interval between the plurality of IC drivers may be 10 times or more of a side length of one of the IC drivers.

In one embodiment, among the substrate, an area of an arrangement region in which the plurality of light emitting devices and the plurality of IC drivers are disposed may be 25% or less of a total area of the substrate.

In one embodiment, the light emitting module may include a common interconnection disposed on one surface of the substrate and commonly connected to the plurality of light emitting devices, and a plurality of auxiliary interconnections respectively connected to the plurality of light emitting devices.

In one embodiment, a thickness of the auxiliary interconnection may be 0.25 times or less of a side length of one of the light emitting devices.

In one embodiment, the plurality of light emitting devices are disposed on one surface of the substrate, and the plurality of IC drivers are disposed on another surface of the substrate.

In one embodiment, at least one of the plurality of light emitting devices may be vertically stacked with one of the IC drivers.

In one embodiment, the light emitting module may further include a light path control layer disposed on at least a part of a region of one surface of the substrate.

In one embodiment, the light path control layer may include a cloaking layer to conceal the plurality of light emitting devices and the plurality of IC drivers from being recognized by a naked eye.

In one embodiment, when a number of the plurality of IC drivers is X (X is a natural number of 1 or more), a number of the plurality of light emitting devices may be X*Y (Y is a natural number of 2 or more).

In one embodiment, the area of the solder for mounting a light emitting device of the light emitting devices on the substrate may be 25% to 50% of the area of the light emitting device.

In one embodiment, the thickness of the solder may be 5 μm or more.

In one embodiment, one of the light emitting devices may include a semiconductor layer including a first conductivity type semiconductor layer, a second conductivity type semiconductor layer, and an active layer, and a plurality of electrode pads connected to the semiconductor layer.

In one embodiment, a separation interval between the electrode pads may be 70 μm or more between adjacent two light emitting devices.

In one embodiment, a separation interval between the plurality of electrode pads of the light emitting device may be 50 μm or more.

In one embodiment, one of the light emitting devices may include a plurality of light emitting stacks that emit light of different peak wavelengths and are vertically stacked, a common electrode pad commonly connected to the plurality of light emitting stacks, and a plurality of individual electrode pads respectively connected to the plurality of light emitting stacks.

In one embodiment, the light emitting stack may include a first conductivity type semiconductor layer, an active layer disposed in a partial region of an upper surface of the first conductivity type semiconductor layer, a second conductivity type semiconductor layer disposed on the active layer, an insulation layer covering the first conductivity type semiconductor layer, the active layer, and the second conductivity type semiconductor layer, a first electrode pad disposed on the insulation layer and connected to the first conductivity type semiconductor layer exposed through a first opening of the insulation layer, and a second electrode pad disposed on the insulation layer and connected to the second conductivity type semiconductor layer exposed through a second opening of the insulation layer.

In one embodiment, a diameter of the first opening and the second opening may be 15% or more of a diameter of the first electrode pad and the second electrode pad, respectively.

A light emitting module according to an embodiment of the present invention includes a substrate, a plurality of light emitting devices disposed on the substrate, and a plurality of IC drivers disposed on the substrate to drive the plurality of light emitting devices, wherein an interval between the plurality of light emitting devices is 10 times or more of a side length of the light emitting device.

A light emitting module according to an embodiment of the present invention includes a substrate and a plurality of light emitting devices disposed on the substrate, wherein one of the light emitting devices includes a semiconductor layer including a first conductivity type semiconductor layer, a second conductivity type semiconductor layer, and an active layer, an insulation layer covering the semiconductor layer, and a plurality of electrode pads connected to the semiconductor layer through an opening of the insulation layer, and an interval between the electrode pads is 70 μm or more between adjacent two light emitting devices.

An embodiment of the present invention may provide a light emitting module and a light emitting apparatus including the same, which can secure sufficient transparency.

An embodiment of the present invention may provide a light emitting module and a light emitting apparatus including the same, which have a high color reproduction rate using red, green, and blue light emitting devices.

An embodiment of the present invention may provide a light emitting module and a light emitting apparatus including the same, with improved driving reliability by reducing heat generation of a plurality of light emitting devices.

An embodiment of the present invention may provide a light emitting module and a light emitting apparatus including the same, in which structural stability can be improved even in a flexible structure.

In addition, an embodiment of the present invention may provide a light emitting module and a light emitting apparatus including the same, which can prevent a light emitting device from falling off or solder for mounting the light emitting device from being damaged when a substrate having flexibility is bent.

An embodiment of the present invention may provide a light emitting module and a light emitting apparatus including the same, with improved reliability in a flexible structure.

An embodiment of the present invention may provide a light emitting module and a light emitting apparatus including the same, which can prevent a short circuit in a flexible structure.

### BRIEF DESCRIPTION OF THE DRAWINGS

FIG. 1 is a plan view showing a light emitting module according to an embodiment of the present invention.

FIG. 2 is an enlarged view showing portion A of FIG. 1.

FIG. 3 is a side cross-sectional view showing a part of a light emitting module according to another embodiment of the present invention.

FIG. 4 is a bottom view of the light emitting device of FIG. 3.

FIG. 5 is a side cross-sectional view showing a part of a light emitting module according to another embodiment of the present invention.

FIG. 6 is a modified example of FIG. 5.

FIG. 7 is another modified example of FIG. 5.

FIG. 8 is a bottom view of a light emitting device according to another embodiment of the present invention.

FIG. 9 is a cross-sectional view showing the light emitting device of FIG. 8.

FIG. 10 is a side view showing a light emitting device according to yet another embodiment of the present invention.

FIG. 11 is a bottom view of the light emitting device of FIG. 10.

FIG. 12a is a cross-sectional view in the I-I′ direction of FIG. 11.

FIG. 12b is a cross-sectional view in the II-II′ direction of FIG. 11.

FIG. 13 is a plan view showing a light emitting module according to another embodiment of the present invention.

FIG. 14 is a plan view showing a light emitting module according to yet another embodiment of the present invention.

FIG. 15 is an enlarged view showing portion B of FIG. 14.

FIG. 16 is a diagram illustrating a light emitting module and a vehicle including the same according to another embodiment of the present invention.

FIG. 17 is a diagram illustrating a light emitting module and a light emitting apparatus including the same according to another embodiment of the present invention.

### DETAILED DESCRIPTION

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or redisposed without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

The present invention may provide a light emitting module including a substrate and a plurality of light emitting devices disposed on the substrate. The light emitting module may further include a plurality of IC drivers disposed on the substrate for driving the plurality of light emitting devices. Hereinafter, a preferred embodiment of the present invention will be described in more detail with reference to the accompanying drawings.

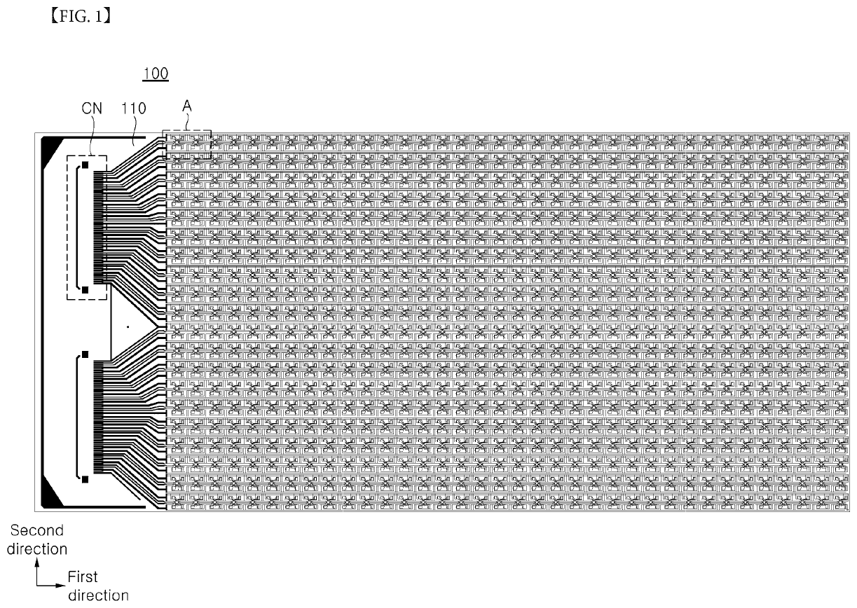

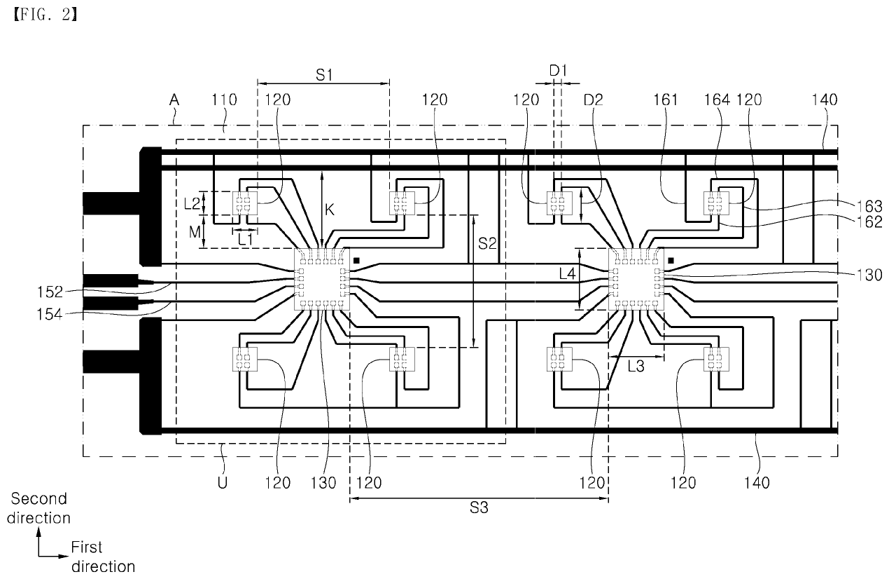

FIG. 1 is a diagram illustrating a light emitting module (100) according to an embodiment of the present invention, and FIG. 2 is an enlarged view showing portion A of FIG. 1. Referring to FIGS. 1 and 2, the light emitting module (100) according to an embodiment of the present invention may include a substrate (110) and a plurality of light emitting devices (120) disposed on the substrate (110). The light emitting module (100) may further include a plurality of IC drivers (130) disposed on the substrate (110) for driving the plurality of light emitting devices (120).

The substrate (110) is a component for supporting the light emitting devices (120) and various configurations are possible. For example, the substrate (110) may be a light-transmitting substrate. Specifically, the substrate (110) may include a base material capable of transmitting light, such as glass, transparent plastic, transparent film, or others.

In addition, the substrate (110) may be a transparent and flexible substrate. For example, the substrate (110) may be a substrate including glass, sapphire, polyimide, acrylic such as PMMA (Polymethyl Methacrylate), PC (Polycarbonate) resin, COP (Cyclo Olefin Polymer), acrylic resin, PE (Polyethylene), or epoxy resin having a property of transmitting light. Alternatively, the substrate (110) may be made of a material having a bendable property, such as polyethylene terephthalate (PET), polyethylene naphthalate (PEN), PVB, or ultra-thin glass (UTG).

FIG. 1 illustrates an example in which the substrate (110) has a rectangular shape, but the present invention is not limited thereto.

The light emitting module (100) may include a metal pattern disposed on one surface of the substrate (110). The metal pattern may be disposed only on one surface of the substrate (110) or on both surfaces. The light emitting device (120) may be mounted on the metal pattern.

The metal pattern may be composed of various materials. The metal pattern may be made of a material with a resistivity of 1×10⁻⁴ Ω·cm or less. More preferably, the metal pattern may include a material with a resistivity of 3×10⁻⁶ Ω·cm or less. For example, the metal pattern may be made of a metal material such as Cu, Au, AuSn, Fe, Al, Ag, or W. In addition, the metal pattern may be made of a transparent electrode composed of a compound of the metal or an oxide such as indium tin oxide (ITO) or manganese oxide, PEDOT, a nanowire such as a silver nanowire, or a carbon nanotube.

In addition, the metal pattern can reduce the interference of the metal pattern or increase transparency by thinly disposing a metal material. For example, the metal pattern may secure light transmittance and electrical conductivity by using a metal mesh. At this time, to secure light transmittance, the width of the metal pattern may be 50 μm or less. In addition, the interval between wires of the metal pattern may be 50 μm or more. For example, the interval between wires of the metal pattern may be 200 μm.

In addition, the metal pattern may be formed of a transparent electrode having transmittance, such as indium tin oxide (ITO), ZnO, aluminum-doped zinc oxide (AZO), or gallium-doped zinc oxide (GZO), to increase transparency.

A plurality of the metal patterns may be provided, and one of the metal patterns may be made of a material different from other metal patterns. In addition, the widths of the metal patterns may be the same or different. The area or thickness of the metal pattern may be designed in consideration of the power consumption of the light emitting device connected to the metal pattern. As an example, the width of a metal pattern to which one light emitting device (120) is connected may be narrower than the width of a conductive pattern to which a plurality of light emitting devices (120) are connected. In addition, the metal patterns may be spaced apart from each other in a vertical direction for complex connections. The conductive patterns may be disposed on different layers of the substrate (110).

Some of the metal patterns may have a potential difference. The on/off operation of the light emitting device (120) may be controlled by adjusting the potential difference. For operation control, some of the metal patterns may perform the roles of a drain and a gate of the light emitting device (120). A thin-film transistor (TFT) circuit may be included in some regions of the metal patterns.

The light emitting device (120) is a light source disposed on the upper surface of the substrate (110), and various configurations are possible. For example, the light emitting device (120) may be a light emitting diode including a semiconductor layer formed on a growth substrate.

The growth substrate is not limited to a specific substrate as long as it is a substrate on which a nitride-based semiconductor can be grown, and may include, for example, a heterogeneous substrate such as a sapphire substrate, a gallium arsenide substrate, a silicon substrate, a silicon carbide substrate, or a spinel substrate, and may also include a homogeneous substrate such as a gallium nitride substrate or an aluminum nitride substrate. The growth substrate may be removed after the semiconductor layer is grown.

The light emitting device (120) may include a first conductivity type semiconductor layer, a second conductivity type semiconductor layer, and an active layer disposed between the first conductivity type semiconductor layer and the second conductivity type semiconductor layer to generate light.

The first conductivity type semiconductor layer may be a semiconductor layer grown on one surface of the growth substrate, and a buffer layer (not shown) may be additionally formed between the first conductivity type semiconductor layer and the growth substrate.

The first conductivity type semiconductor layer may include a phosphide or nitride-based semiconductor such as (Al, Ga, In)P or (Al, Ga, In)N, and may be formed by being grown on the growth substrate using a method such as MOCVD, MBE, HVPE, or others. In addition, the first conductivity type semiconductor layer may be doped as n-type by including one or more impurities such as Si, C, Ge, Sn, Te, Pb, or others. However, the present invention is not limited thereto, and the first conductivity type semiconductor layer may be doped with an opposite conductivity type including a p-type dopant.

In addition, further, the first conductivity type semiconductor layer may be formed as a single layer or multiple layers. Furthermore, the first conductivity type semiconductor layer may further include a contact layer, a modulation doping layer, an electron injection layer, or others.

The active layer is a light emitting layer disposed on one surface of the first conductivity type semiconductor layer, may include a phosphide or nitride semiconductor such as (Al, Ga, In)P or (Al, Ga, In)N, and may be grown on the first conductivity type semiconductor layer using a technique such as MOCVD, MBE, or HVPE.

In addition, the active layer may include a quantum well structure (QW) including at least two barrier layers and at least one well layer, and further, may include a multi-quantum well structure (MQW) including a plurality of barrier layers and a plurality of well layers.

A wavelength of light emitted from the active layer may be adjusted by controlling a composition ratio of materials forming the well layer. In this case, the well layer may include the same element in common, for example, In.

The second conductivity type semiconductor layer may be a semiconductor layer disposed on one surface of the active layer. The second conductivity type semiconductor layer may include a phosphide or nitride-based semiconductor such as (Al, Ga, In)P or (Al, Ga, In)N, and may be grown using a technique such as MOCVD, MBE, or HVPE. The second conductivity type semiconductor layer may be doped with a conductivity type opposite to that of the first conductivity type semiconductor layer. For example, the second conductivity type semiconductor layer may be doped as p-type by including an impurity such as Mg.

The second conductivity type semiconductor layer may be formed as a single layer having a composition such as p-GaN, without being limited thereto, and may further include an AlGaN layer therein.

In addition, the light emitting device (120) may further include an insulation layer covering the first conductivity type semiconductor layer, the active layer, and the second conductivity type semiconductor layer, and first and second electrode pads respectively connected to the first conductivity type semiconductor layer and the second conductivity type semiconductor layer through openings provided in the insulation layer. The first electrode pad may be disposed on the insulation layer and connected to the first conductivity type semiconductor layer exposed through a first opening of the insulation layer. The second electrode pad may be disposed on the insulation layer and connected to the second conductivity type semiconductor layer exposed through a second opening of the insulation layer.

At this time, the diameter of the first opening and the second opening may be 15% or more of the diameter of the first electrode pad and the second electrode pad, respectively. The area of the first opening and the second opening may be 25% or more of the area of the first electrode pad and the second electrode pad, respectively.

The first and second electrode pads may be electrically connected to the substrate (110) through connection electrodes. However, the embodiment of the present invention is not limited thereto, and bumps may be formed on the electrode pads without connection electrodes to be connected to the metal pattern of the substrate (110) through a bonding material, or the electrode pads may be electrically connected to the metal pattern of the substrate (110) through soldering. Of course, various other mounting methods are possible.

The first and second electrode pads may include a material with a resistivity of 1×10⁴ Ω·cm or less to supply current to the first and second conductivity type semiconductor layers of the light emitting device (120). To satisfy these conditions, the electrode pad may be made of a metal material such as copper, gold, silver, tin, iron, or aluminum. Alternatively, the electrode pad may be made of a transparent electrode composed of a compound of the metal or an oxide such as indium tin oxide (ITO) or manganese oxide, a conductive polymer (PEDOT:PSS, Poly(3,4-ethylenedioxythiophene):poly(styrenesulfonate)), a nanowire such as a silver nanowire, or a carbon nanotube.

Meanwhile, the first conductivity type semiconductor layer, the active layer, and the second conductivity type semiconductor layer constitute one light emitting stack, and the light emitting device (120) may include one light emitting stack or a plurality of light emitting stacks. Alternatively, one light emitting device (120) may be composed of a plurality of light emitting diodes. For example, the light emitting device (120) may include a plurality of light emitting diodes having three or more different peak wavelengths. For example, a first light emitting diode may have a peak wavelength between 400 nm and 470 nm, a second light emitting diode may have a peak wavelength between 600 nm and 700 nm, and a third light emitting diode may have a peak wavelength between 500 nm and 540 nm. As such, when using a plurality of light emitting diodes having three different peak wavelengths, it is possible to express various colors through color mixing as well as the three primary colors of light, thereby improving image quality.

In addition, the peak wavelengths of light emitted from each light emitting device (120) may be the same or different. Alternatively, the light emitting devices (120) may be composed of devices that emit light of the same color gamut, and for example, may be composed of light emitting devices (120) in which the difference in dominant wavelength between adjacent light emitting devices (120) is 2 nm to 15 nm. Through this, more vivid colors can be implemented.

For example, one of the light emitting devices (120) may be a diode that emits blue light, may be a blue light emitting diode having a peak wavelength within a blue wavelength range, and a difference between the peak wavelength and a dominant wavelength of the blue light emitting diode may be between 2 nm and 15 nm. Specifically, the blue light emitting diode may have a peak wavelength between 430 nm and 475 nm, and may have a dominant wavelength between 460 nm and 480 nm. By maintaining the difference in peak wavelengths, color deviation is lowered, enabling a more vivid color expression. The peak wavelength of the blue light emitting diode may be shorter than the dominant wavelength. Through this, it is possible to increase light energy while correcting luminous sensitivity, thereby lowering design difficulty.

One of the light emitting devices (120) may be a diode that emits green light, may be a green light emitting diode having a peak wavelength within a green wavelength range, and a difference between the peak wavelength and the dominant wavelength may be between 5 nm and 20 nm. Specifically, the green light emitting diode may have a peak wavelength between 510 nm and 540 nm, and may have a dominant wavelength between 525 nm and 545 nm. By maintaining the difference in peak wavelengths, color deviation is lowered, enabling a more vivid color expression. The peak wavelength of the green light emitting diode may be shorter than the dominant wavelength. Through this, it is possible to increase light energy while correcting luminous sensitivity, thereby lowering design difficulty.

One of the light emitting devices (120) may be a diode that emits red light, may be a red light emitting diode having a peak wavelength within a red wavelength range, and a difference between the peak wavelength and the dominant wavelength may be between 5 nm and 30 nm. Specifically, the red light emitting diode may have a peak wavelength between 620 nm and 640 nm, and may have a dominant wavelength between 600 nm and 630 nm. By maintaining the difference in peak wavelengths, color deviation is lowered, enabling a more vivid color expression. The peak wavelength of the red light emitting diode may be longer than the dominant wavelength. Through this, it is possible to increase light energy while correcting luminous sensitivity, thereby lowering design difficulty.

The light emitting device (120) may also be configured to emit orange light, yellow light, purple light, or ultraviolet light in addition to blue, green, and red light. The light emitting device (120) may further include a wavelength conversion material for emitting light of various colors.

The light emitting device (120) may have various shapes, and for example, may be formed in a rectangular shape as illustrated in FIG. 2. The light emitting device (120) may have a square shape or a rectangular shape with a long side and a short side. For example, the light emitting device (120) may have a rectangular shape in which the length of a side parallel to a first direction is L1 and the length of a side parallel to a second direction perpendicular to the first direction is L2. The L1 and L2 may be 250 μm or less. Or, the L1 and L2 may be 100 μm or less. The longest side length of the light emitting device (120) may be 250 μm or less. For example, the L1 and L2 may be 225 μm.

On the upper surface of the substrate (110), the plurality of light emitting devices (120) may be arranged in various patterns. For example, as illustrated in FIGS. 1 and 2, the light emitting devices (120) may be arranged in a matrix form along the first direction and the second direction. For example, three light emitting devices (120) that emit red, green, and blue light may be arranged at regular intervals to form one group or pixel. The light emitting devices (120) may reproduce light of a wide color gamut using red, green, and blue light. As another example, one light emitting device (120) may include three light emitting stacks that are vertically stacked and emit red, green, and blue light, respectively, to form one pixel. As yet another example, one light emitting device (120) may include sub-pixels arranged horizontally that emit red, green, and blue light, respectively, to form one pixel.

Referring to FIG. 2, the interval (S1, S2) between the plurality of light emitting devices (120) may be 10 times or more of a side length (L1, L2) of the light emitting device (120). For example, if the side length (L1, L2) of the light emitting device (120) is 250 μm, the interval (S1, S2) between the light emitting devices (120) may be 2.5 mm or more. By arranging the light emitting devices (120) at a sufficiently wide interval, the transparency of the light emitting module (100) can be secured.

FIG. 3 shows a light emitting device (120) according to an embodiment of the present invention. Referring to FIG. 3, the light emitting device (120) may include a plurality of vertically stacked light emitting stacks (301, 302, 303). The plurality of light emitting stacks (301, 302, 303) may emit light of different peak wavelengths.

The light emitting device (120) may include a first light emitting stack (301), a second light emitting stack (302) disposed on one side of the first light emitting stack (301), and a third light emitting stack (303) disposed on one side of the second light emitting stack (302).

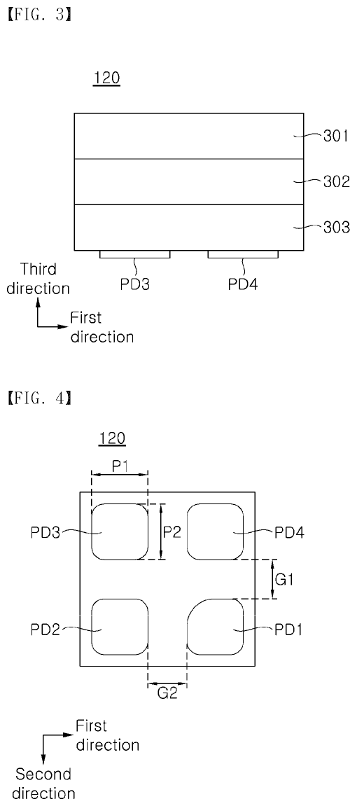

Each of the first to third light emitting stacks (301, 302, 303) may include a first conductivity type semiconductor layer, an active layer, and a second conductivity type semiconductor layer. In addition, the light emitting device (120) may include an adhesive layer, an insulation layer, and electrode pads for adhering the first to third light emitting stacks (301, 302, 303). FIG. 4 shows one surface of the light emitting device (120) of FIG. 3, on which electrode pads (PD1, PD2, PD3, PD4) of the light emitting device (120) may be disposed.

The electrode pads (PD1, PD2, PD3, PD4) may include a common electrode pad (PD1) commonly connected to the plurality of light emitting stacks (301, 302, 303), and a plurality of individual electrode pads (PD2, PD3, PD4) respectively connected to the plurality of light emitting stacks (301, 302, 303). The plurality of light emitting stacks (301, 302, 303) may be electrically connected to the substrate (110) through the plurality of electrode pads (PD1, PD2, PD3, PD4).

The electrode pads (PD1, PD2, PD3, PD4) may have various shapes, and for example, may have a rectangular planar shape overall. As an example, one side length (P1, P2) of the electrode pads (PD1, PD2, PD3, PD4) may be 75 μm or less. For example, the side length (P1, P2) of the electrode pads (PD1, PD2, PD3, PD4) may be 72.5 μm. To maintain transparency, the area of the electrode pads (PD1, PD2, PD3, PD4) may be less than 40% of the area of the light emitting device (120). However, to prevent the light emitting device (120) from falling off due to external impact, the area of the electrode pads (PD1, PD2, PD3, PD4) may have an area of at least 20% of the area of the light emitting device (120).

In addition, a separation interval (G1, G2) between the electrode pads (PD1, PD2, PD3, PD4) within the light emitting device (120) may be 45 μm or more. For example, the separation interval (G1, G2) may be 50 μm. Through this, a short circuit between each of the electrode pads (PD1, PD2, PD3, PD4) can be prevented, thereby improving reliability.

The first to third light emitting stacks (301, 302, 303) may be a light emitting stack that emits red light, a light emitting stack that emits green light, and a light emitting stack that emits blue light, respectively. Therefore, one stacked light emitting device (120) including the first to third light emitting stacks (301, 302, 303) may display RGB primary colors as a pixel.

However, the light emitting device (120) is not limited to a specific structure, and may be implemented by being modified into various structures. It is obvious that the light emitting device (120) can be modified into various structures such as a flip-chip type, a vertical type, a lateral type, and others. In addition, depending on the shape of the light emitting device (120), a growth substrate may be omitted.

Again, referring to FIGS. 1 and 2, the light emitting module (100) may further include a plurality of IC drivers (130) disposed on the substrate (110) for driving the plurality of light emitting devices (120). The IC drivers (130) may be disposed in various numbers at various positions on the substrate (110). The IC drivers (130) may be disposed on the same surface of the substrate (110) where the light emitting devices (120) are disposed, or on the opposite surface thereof. In addition, a connector connection part (CN) for connecting the IC driver (130) and a processor may be disposed on one side of an edge of the substrate (110).

The IC driver (130) is a component for driving the plurality of light emitting devices (120) and various configurations are possible. The IC driver (130) may provide the current and voltage required for the light emitting device (120) and control the on/off operation. The IC driver (130) may be connected to the processor through the connector connection part (CN).

The IC driver (130) may have a rectangular shape in a plan view. For example, the IC driver (130) may have a rectangular shape in which a length of a side parallel to a first direction is L3 and a length of a side parallel to a second direction perpendicular to the first direction is L4. The L3 and L4 may be 650 μm or less. The specification of the IC driver (130) may be configured in various ways according to the design and is not limited to a specific size. At this time, the long side length of the light emitting device (120) may be 650 μm or less. For example, the L1 and L2 may be 600 μm.

The IC drivers (130) may be disposed in various patterns on one surface of the substrate (110). For example, as illustrated in FIGS. 1 and 2, the IC drivers (130) may be disposed in a matrix form along the first direction and the second direction, but are not limited thereto.

At this time, an interval (S3) between the plurality of IC drivers (130) may be 10 times or more of a side length (L3, L4) of the plurality of IC drivers (130). For example, if the side length (L3, L4) of the IC driver (130) is 400 μm, the interval (S3) of the IC driver (130) may be 4 mm or more. The plurality of IC drivers (130) may be spaced apart from each other in the first direction or the second direction. The interval (S3) between adjacent IC drivers (130) in the first direction or the second direction may be 4 mm or more. By disposing the IC drivers (130) at a sufficiently wide interval, the transparency of the light emitting module (100) can be secured.

The area of the IC driver (130) may be larger than that of the light emitting device (120). For example, the area of the IC driver (130) may be 7 times or more of the area of the light emitting device (120).

To secure transparency, the IC driver (130) may drive a plurality of light emitting devices. The IC drivers (130) may be respectively connected to a plurality of light emitting devices (120). As a result, the number of the plurality of IC drivers (130) disposed on the substrate (110) may be smaller than the number of the plurality of light emitting devices (120). For example, the plurality of IC drivers (130) may be respectively connected to Y light emitting devices (120) (Y is a natural number of 2 or more). One IC driver (130) is connected to Y light emitting devices (120) to drive the Y light emitting devices (120).

When the number of the plurality of IC drivers (130) is X (X is a natural number of 1 or more), the number of the plurality of light emitting devices (120) may be X*Y (Y is a natural number of 2 or more). One IC driver (130) and the Y light emitting devices (120) connected thereto may form one light emitting unit (U). The light emitting units (U) may be disposed along the first direction and the second direction. Due to the relatively large size, by arranging fewer IC drivers (130) than the light emitting devices (120), the transparency and flexibility of the light emitting module (100) can be maintained.

For example, referring to FIG. 2, one IC driver (130) may be connected to four light emitting devices (120). The IC driver (130) may be surrounded by the connected Y light emitting devices (120). The IC driver (130) may be disposed at an inner center of a rectangular region formed by the four light emitting devices (120). However, the present invention is not limited thereto, and the IC driver (130) may be disposed in a region of the light emitting module (100) spaced apart from the light emitting devices (120).

Among the substrate (110), an area of an arrangement region (i.e., opaque region) in which the plurality of light emitting devices (120) and the plurality of IC drivers (130) are disposed may be 25% or less of a total area. In particular, within one light emitting unit (U), an area of an arrangement region (i.e., opaque region) occupied by the light emitting devices (120) and one IC driver (130) may be 25% or less of the area of the light emitting unit (U). The area of the IC driver (130) may be 1.8 times or less of the area occupied by the Y light emitting devices (120) connected to the IC driver (130). More preferably, the area of the IC driver (130) may be 1.4 times or less of the area occupied by the Y light emitting devices (120) connected to the IC driver (130). In addition, to secure transparency, an interval (S3) between the IC drivers (130) may be greater than the intervals (S1, S2) between the light emitting devices (120). Through this, it is possible to prevent the transparency from being reduced by the IC driver (130) with a wide arrangement area.

Meanwhile, an interval (M) between the IC driver (130) and an adjacent light emitting device (120) may be 70 μm or more. Preferably, the interval (M) may be 70 μm or more.

The electrode pads (PD1, PD2, PD3, PD4) of the light emitting device (120) may be electrically connected to a metal pattern disposed on one surface of the substrate (110). Referring to FIG. 2, the metal pattern may include a common interconnection (140) commonly connected to the plurality of light emitting devices (120), and a plurality of auxiliary interconnections (161, 162, 163, 164) respectively connected to the plurality of light emitting devices (120).

The common interconnection (140) is connected to an external processor through the connector connection portion (CN) disposed on one side of the substrate (110), and may be an interconnection for providing a common cathode or common power source (Vcc).

The common interconnection (140) may be disposed outside of an edge of the substrate (110). In more detail, the common interconnection (140) may extend along the first direction (or second direction) outside of an edge of one surface of the substrate (110).

The common interconnection (140) may be provided in a plurality. When the common interconnection (140) is formed to extend along the first direction, the plurality of common interconnections (140) may be spaced apart from one another along the second direction. The light emitting device (120) and the IC driver (130) may be disposed between the common interconnections (140). A distance (K) from the IC driver (130) to the common interconnection (140) may be 1.5 to 2 times or less of a side length (L3, L4) of the IC driver (130). For example, when the side length (L3, L4) of the IC driver (130) is 650 μm, the distance (K) to the common interconnection (140) may be 1.7 mm or less. For example, the distance (K) may be 1.6 mm or less.

Since the common interconnection (140) is connected to multiple light emitting devices (120) and multiple IC drivers (130), its thickness may be relatively large. For example, the thickness of the common interconnection (140) may be larger than the side length (L1, L2) of the light emitting device (120). The thickness of the common interconnection (140) may be 350 μm. Accordingly, with respect to one light emitting unit (U), the common interconnection (140) may be disposed outside of the light emitting unit (U). Through this, it is possible to prevent the relatively thick common interconnection (140) from covering a light emitting region of the light emitting unit (U).

The auxiliary interconnections (161, 162, 163, 164) may be interconnections connected to the light emitting device (120). A thickness of the auxiliary interconnections (161, 162, 163, 164) may be smaller than that of the common interconnection (140). For example, the thickness of the auxiliary interconnections (161, 162, 163, 164) may be 0.25 times or less of the side length (L1, L2) of the light emitting device (120). As another example, the thickness of the auxiliary interconnections (161, 162, 163, 164) may be 0.5 times or less of the side length (P1, P2) of the electrode pads (PD1, PD2, PD3, PD4) of the light emitting device (120).

The auxiliary interconnections (161, 162, 163, 164) are interconnections disposed adjacent to the light emitting device (120), and transparency can be secured by making their thickness small within the light emitting unit (U), which is a transparent region. In addition, through this, the influence on the bending radius of the light emitting module (100) can be minimized.

One auxiliary interconnection (161) among the auxiliary interconnections (161, 162, 163, 164) connected to one light emitting device (120) may be a branch interconnection branched from the common interconnection (140). The remaining auxiliary interconnections (162, 163, 164) may be connecting interconnections connecting the IC driver (130) and the light emitting device (120). For example, when the light emitting device (120) of FIG. 3 is disposed on the substrate (110), the branch interconnection may be connected to the common electrode pad (PD1) of the light emitting device (120), and the connecting interconnections may be connected to the individual electrode pads (PD2, PD3, PD4) of the light emitting device (120).

Two of the auxiliary interconnections (161, 162, 163, 164) may be disposed parallel to each other in the first direction in at least some sections. A second direction interval (D2) between the two auxiliary interconnections (161, 162, 163, 164) disposed parallel in the first direction may be larger than a side length (L1, L2) of the light emitting device (120). For example, when the light emitting device (120) is 225 μm, the second direction interval (D2) between the two auxiliary interconnections (161, 162, 163, 164) may be 0.6 mm or less. For example, the second direction interval (D2) may be 0.58 mm.

In addition, two of the auxiliary interconnections (161, 162, 163, 164) may be disposed parallel to each other in the second direction in at least some sections. A first direction interval (D1) between the two auxiliary interconnections (161, 162, 163, 164) disposed parallel in the second direction may be smaller than the second direction interval (D2). For example, the first direction interval (D1) may be 0.13 mm or less. For example, the first direction interval (D1) may be 0.122 mm.

Meanwhile, the common interconnection (140) or the auxiliary interconnections (161, 162, 163, 164) may be disposed on one surface or both surfaces of the substrate (110). Through this, a complex interconnection can be simplified and transparency can be improved.

The common interconnection (140) may also be connected to the IC driver (130) through an additional auxiliary interconnection. In addition, the metal pattern may further include signal interconnections (152, 154) for transmitting a control signal and a clock signal to the IC driver (130).

In a case of FIGS. 1 and 2, it is exemplarily illustrated that the light emitting device (120) and the IC driver (130) are disposed on a same surface of the substrate (110), but the present invention is not limited thereto. Of course, an example in which the light emitting device (120) and the IC driver (130) are disposed on different surfaces of the substrate (110) is also possible.

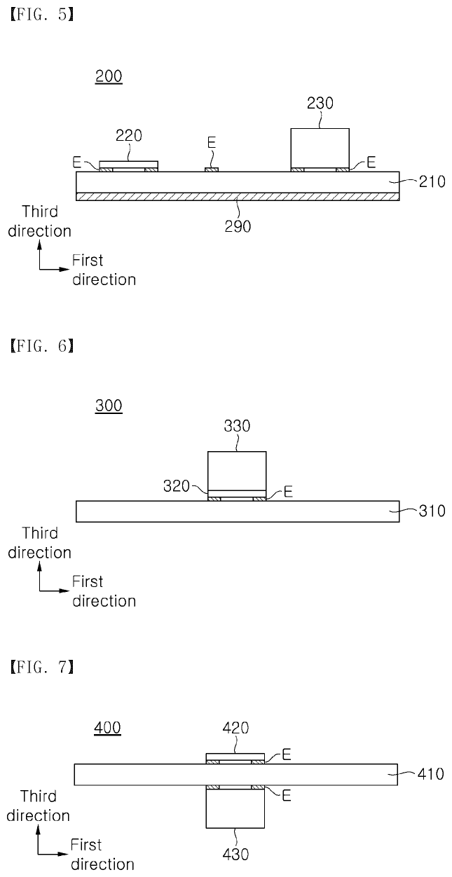

Next, FIG. 5 illustrates alight emitting module (200) according to another embodiment of the present invention. The light emitting module (200) may include a substrate (210), a plurality of light emitting devices (220) disposed on one surface of the substrate (210), and a plurality of IC drivers (230) disposed on one surface of the substrate (210). The substrate (210) may be a light-transmitting substrate.

The light emitting module (200) may be configured to be identical or similar to the light emitting module (100) of FIGS. 1 and 2 except that it further includes a light path layer (290), so descriptions of overlapping configurations are omitted. E in FIG. 5 is a conductive pattern, and it may be configured to be identical or similar to the conductive pattern in FIG. 2, so a detailed description thereof is omitted.

The light path control layer (290) is a layer disposed on at least a partial region of one surface of the substrate (210), and may be disposed on a surface of the substrate (210) opposite to an arrangement surface on which the light emitting device (220) and the IC driver (230) are disposed. Light emitted from the light emitting device (220) may pass through the substrate (210) to be emitted to the outside through the light path control layer (290).

For example, the light path control layer (290) may include a cloaking layer to conceal the plurality of light emitting devices (220) and the plurality of IC drivers (230) from being recognized by a naked eye. The cloaking layer may refract light such that a background behind the light emitting device (220) and the IC driver (230) appears on a surface of the cloaking layer. Accordingly, when viewed from a side of the cloaking layer, the light emitting device (220) and the IC driver (230) behind the cloaking layer may be made invisible to the naked eye. Through this, the light emitting module (200) may be implemented transparently.

As another example, the light path control layer (290) may include a liquid crystal layer that is switched between a transparent state and an opaque state. The liquid crystal layer may be a Polymer Dispersed Liquid Crystal (PDLC) film in which a polymer liquid crystal is dispersed between two ITO films. Depending on a power on/off, the liquid crystal layer may be switched between the transparent state and the opaque state. Accordingly, when necessary, the light emitting module (200) may be used as a transparent display.

As another example, the light path control layer (290) may include at least one of a coating layer, a lens, and a light absorption layer.

Next, FIG. 6 illustrates a light emitting module (300) according to yet another embodiment of the present invention. The light emitting module (300) may include a substrate (310), a plurality of light emitting devices (320) disposed on one surface of the substrate (310), and a plurality of IC drivers (330) disposed on one surface of the substrate (310). The substrate (310) may be a light-transmitting substrate.

The light emitting module (300) may be configured to be identical or similar to the light emitting module (100) of FIGS. 1 and 2 except that the light emitting device (320) and the IC driver (330) are vertically stacked, so descriptions of overlapping configurations are omitted. E in FIG. 6 is a conductive pattern, and it may be configured to be identical or similar to the conductive pattern in FIG. 2, so a detailed description thereof is omitted.

In FIG. 6, at least one of a plurality of light emitting devices (320) may be vertically stacked with the IC driver (330). FIG. 6 exemplarily illustrates that the IC driver (330) is disposed in an upper side of the light emitting device (320), but an example in which the light emitting device (320) is disposed in an upper side of the IC driver (330) is also possible. Through this, a transparency of the light emitting module (300) may be further secured.

Next, FIG. 7 illustrates alight emitting module (400) according to another embodiment of the present invention. The light emitting module (400) may include a substrate (410), a plurality of light emitting devices (420) disposed on one surface of the substrate (410), and a plurality of IC drivers (430) disposed on one surface of the substrate (410). The light emitting module (400) may be configured to be identical or similar to the light emitting module (100) of FIGS. 1 and 2 except that the light emitting device (420) and the IC driver (430) are disposed on different surfaces of the substrate (410), so descriptions of overlapping configurations are omitted. E in FIG. 7 is a conductive pattern, and it may be configured to be identical or similar to the conductive pattern in FIG. 2, so a detailed description thereof is omitted.

In FIG. 7, the plurality of light emitting devices (420) may be disposed on one surface of the substrate (410), and the plurality of IC drivers (430) may be disposed on the other surface of the substrate (410). The light emitting device (420) and the IC driver (430) disposed on different surfaces of the substrate (410) may be overlapped vertically. Through this, a transparency of the light emitting module (400) may be further secured.

The light emitting modules (100, 200, 300, 400) of the above-described embodiments include a light-transmitting substrate (110, 210, 310, 410), and the geometric transparency (TP) of the light emitting modules (100, 200, 300, 400) may be 50% or more. The geometric transparency (TP) may be calculated by a following equation 1.

$$Equation ( 1 )$$

$$Transparency ( TP ) = \frac{\begin{matrix}Unit area - ( Area of light emitting devices within \\ unit area + Area of IC drivers within unit area )\end{matrix}}{Unit area}$$

Herein, a unit area may be an area of a region including sets of light emitting units U connected to a connector connection portion CN. The transparency (TP) is a unitless value, which may have a value between 0 and 1, and the closer the transparency (TP) is to 1, the more transparent is the light emitting module.

In addition, the geometric transparency (TP) of one light emitting unit U may be higher than the geometric transparency (TP) of sets of light emitting units U including the connector connection portion CN. For this purpose, the common interconnection (140) may be disposed outside of the light emitting unit (U). Through this, it is possible to increase a light transmittance of a light emitting region, thereby improving visual transparency.

As a modification of the light emitting module (100) of FIGS. 1 and 2, the substrate (110) may be a transparent or opaque flexible substrate. The substrate (110) is a flexible component that supports the light emitting devices (120), and for example, may be a flexible printed circuit board (FPCB). The flexible substrate (110) may be made of a polymer plastic such as polyimide (PI) or polyester film, but is not limited thereto.

The substrate (110) is relatively thin and flexible, so it can save space or implement a display with a natural viewing angle. The substrate (110) may be a substrate having flexibility and light-transmitting properties.

Specifically, the substrate (110) may be made of various materials such as PC (Polycarbonate), PES (Polyether Sulfone), PET (Polyethylene Terephthalate), PEN (Polyethylene Naphthalate), PI (Polyimide), PAR (Polyarylate), COC (Cyclo Olefin), composite material (FPR, Glass Fiber Reinforced Plastic), polymethyl methacrylate (PMMA), and others.

In addition, the interval (S1, S2) between the plurality of light emitting devices (120) may be 50 μm or more and 250 μm or less. Specifically, the interval (S1, S2) between adjacent light emitting devices (120) in the first direction or the second direction may be 50 μm or more and 250 μm or less. By sufficiently securing the interval (S1, S2) between the light emitting devices (120), it is possible to prevent problems such as interference, falling off, or damage between the light emitting devices (120) when the flexible substrate (110) is bent.

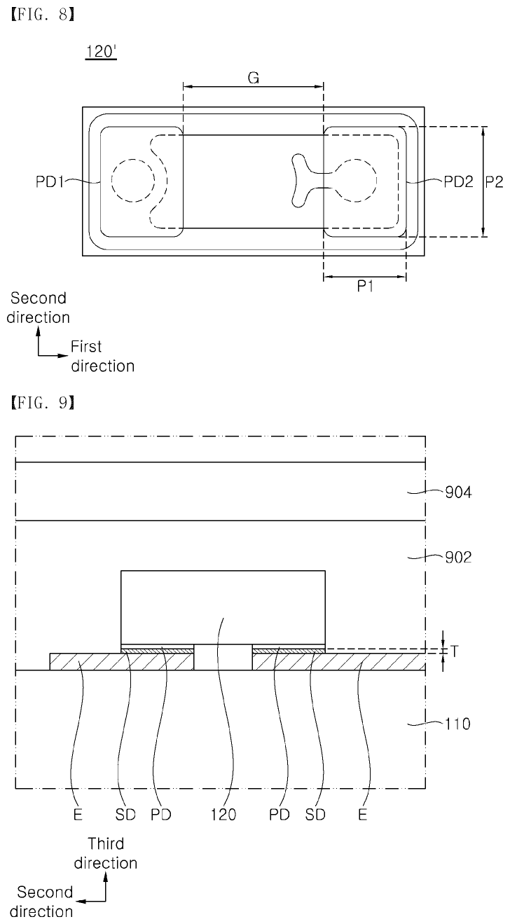

Meanwhile, FIG. 8 is a bottom view of a light emitting device (120′), which is a modification of the light emitting device (120) described above. Electrode pads (PD1, PD2) may be disposed on the bottom surface of the light emitting device (120′). FIG. 9 is a cross-sectional view showing the light emitting device (120′) of FIG. 8 disposed on one surface of the substrate (110). In the light emitting device (120′), the interval (G) between the electrode pads (PD1, PD2) may be 50 μm or more. Through this, a short circuit between the electrode pads (PD1, PD2) can be prevented.

In addition, the separation interval between the electrode pads (PD1, PD2) may be 70 μm or more between two adjacent light emitting devices (120′) in FIG. 8. By sufficiently securing the separation interval (G) between the electrode pads (PD1, PD2), damage such as interference or cracks between the electrode pads (PD1, PD2) can be prevented when the flexible substrate (110) is bent.

The electrode pads (PD1, PD2) may have various shapes, and for example, may have a rectangular planar shape overall. Side lengths (P1, P2) of the electrode pads (PD1, PD2) may be 2 mm or less. The side lengths (P1, P2) of the electrode pads (PD1, PD2) may be 20% or more and 80% or less of the length of one side (L1, L2) of the light emitting device (120′). As an example, the side length (P1) in the major axis direction (second direction) of the electrode pads (PD1, PD2) may have a length of 20% or more of the side length in the major axis direction (first direction) of the light emitting device (120′). Through this, a short circuit between the electrode pads (PD1, PD2) can be prevented. As another example, the side length (P2) in the minor axis direction of the electrode pads (PD1, PD2) may have a length of less than 80% of the length of the side in the minor axis direction of the light emitting device (120′). Through this, sufficient adhesion can be secured.

Meanwhile, in FIG. 9, E is a metal pattern disposed on one surface of the substrate (110), and the electrode pads (PD1, PD2) of the light emitting device (120′) may be connected to the metal pattern (E) of the substrate (110) through solder (SD). The solder (SD) is a component for mounting the light emitting device (120′) on the substrate (110), and various configurations are possible.

The thickness (T) of the solder (SD) may be 5 μm or more. Through this, adhesion can be secured. As another example, the thickness (T) of the solder (SD) may be 10 μm or less. Through this, the tilting of the light emitting device (120′) can be reduced.

The bonding area of the solder (SD) with the metal pattern (E) may be 25% to 50% of the planar area of the light emitting device (120′). By setting the area of the solder (SD) to about 40% of the area of the light emitting device (120′), damage such as cracking of the solder (SD) can be prevented when the substrate (110) is bent.

Referring to FIG. 9, the light emitting module (100) may further include a molding layer (902) covering the light emitting device (120′) disposed on the flexible substrate (110). In addition, the light emitting module (100) may further include a coating layer (904) disposed on the molding layer (902). The molding layer (902) and the coating layer (904) may also be made of a bendable material.

The coating layer (904) may be made of a material such as PET, silicone, epoxy, Fused silica, borosilicate, soda-lime glass, aluminosilicate, Fluoropolymer, Polyphthalamide (PPA), polybutylene terephthalate (PBT), or Polycarbonate (PC).

Alternatively, the coating layer (904) may be an anti-glare layer that can prevent glare.

Alternatively, the coating layer (904) may be a film layer formed through a matt treatment. For example, the coating layer (904) may be a non-glossy film layer in which a matt film attached to the upper part of the molding layer (902) is surface-treated. In addition, additives such as TiO2, BaSO4, Cr, C, etc. may be added to the coating layer (904) to modify the light path.

The thickness of the coating layer (904) may be formed thinner than the thickness of the molding layer (904). In addition, it may become thicker from the central part to the outer part of the light emitting module (100).

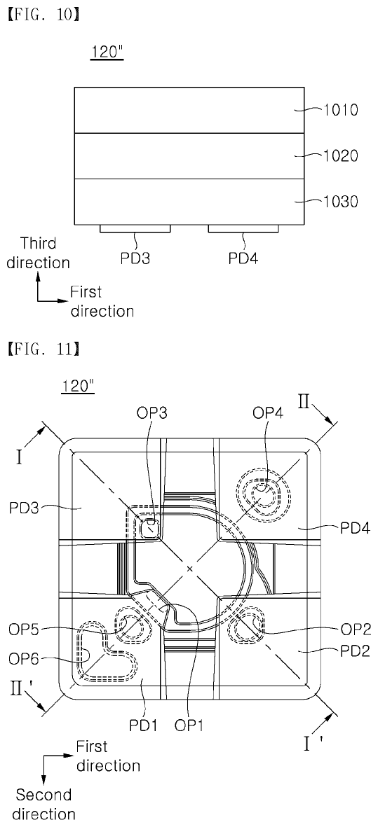

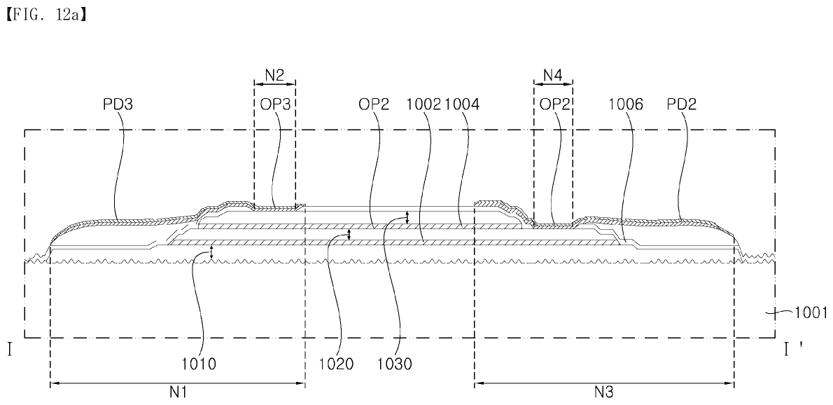

Next, a light emitting device (120″) of FIGS. 10 and 11 is a modification of the light emitting devices (120, 120′) described above. The light emitting device (120″) may include a plurality of vertically stacked light emitting stacks (1010, 1020, 1030). The plurality of light emitting stacks (1010, 1020, 1030) may emit light of different peak wavelengths.

The light emitting device (120″) may include a first light emitting stack (1010), a second light emitting stack (1020) disposed on one side of the first light emitting stack (1010), and a third light emitting stack (1030) disposed on one side of the second light emitting stack (1020).

Each of the first to third light emitting stacks (1010, 1020, 1030) may include a first conductivity type semiconductor layer, an active layer, and a second conductivity type semiconductor layer. In addition, the light emitting device (120″) may include an adhesive layer, an insulation layer, and electrode pads for adhering the first to third light emitting stacks (1010, 1020, 1030).

FIG. 11 shows one surface of the light emitting device (120″) including the first to third light emitting stacks (1010, 1020, 1030), on which electrode pads (PD1, PD2, PD3, PD4) of the light emitting device (120″) may be disposed.

The electrode pads (PD1, PD2, PD3, PD4) may include a common electrode pad (PD1) commonly connected to the plurality of light emitting stacks (1010, 1020, 1030), and a plurality of individual electrode pads (PD2, PD3, PD4) respectively connected to the plurality of light emitting stacks (1010, 1020, 1030). The plurality of light emitting stacks (1010, 1020, 1030) may be electrically connected to the substrate (110) through the plurality of electrode pads (PD1, PD2, PD3, PD4).

The electrode pads (PD1, PD2, PD3, PD4) may have various shapes, and for example, may have a rectangular planar shape overall. Side lengths of the electrode pads (PD1, PD2, PD3, PD4) may have a length of 30% or more and 40% or less of the length of one side of the light emitting device (120″). As an example, the side lengths of the electrode pads (PD1, PD2, PD3, PD4) may be 75 μm or less. For example, the side lengths of the electrode pads (PD1, PD2, PD3, PD4) may be 72.5 μm. In addition, the sum of the areas of the electrode pads (PD1, PD2, PD3, PD4) may be 40% or more and 55% or less of the area of the light emitting device (120″). Through this, a sufficient bonding area is secured to reduce open failures where the bonding solder is detached when the substrate (110) is bent, and to reduce short circuits of the solder (SD) during the process, thereby reducing process difficulty.

In addition, a first direction or second direction separation interval between the electrode pads (PD1, PD2, PD3, PD4) within the light emitting device (120″) may be 20% or more and 30% or less of the length of one side of the light emitting device (120″). As an example, the first direction or second direction separation interval between the electrode pads (PD1, PD2, PD3, PD4) may be 55 μm or less. For example, the separation interval may be 50 μm. Through this, short circuits of the solder (SD) during the process can be reduced, thereby reducing process difficulty.

The first to third light emitting stacks (1010, 1020, 1030) may be a light emitting stack that emits red light, a light emitting stack that emits green light, and a light emitting stack that emits blue light, respectively. Therefore, one stacked light emitting device (120″) including the first to third light emitting stacks (1010, 1020, 1030) may display RGB primary colors as a pixel.

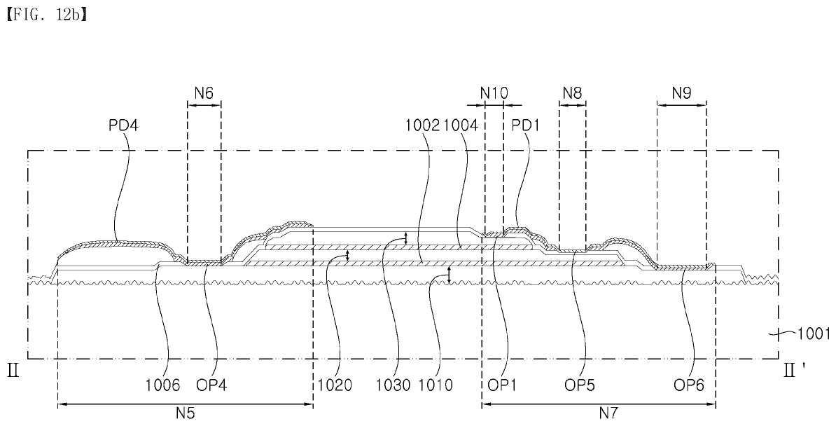

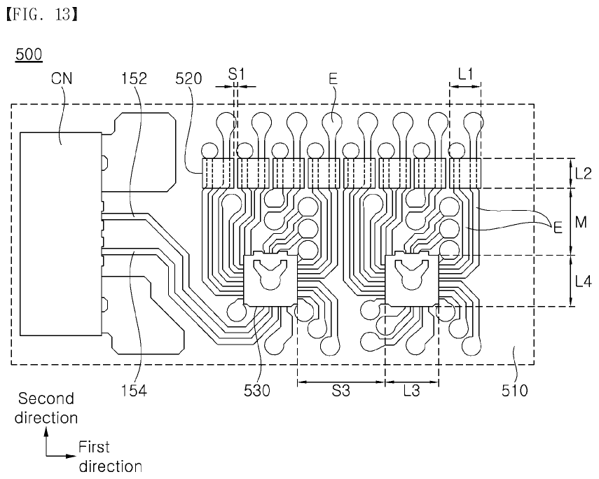

FIG. 12a and FIG. 12b are cross-sectional views in the I-I′ direction and II-II′ direction of the light emitting device (120″) of FIG. 11. Referring to FIGS. 12a and 12b, each light emitting stack (1010, 1020, 1030) of the light emitting device (120″) may include a first conductivity type semiconductor layer, an active layer disposed in a partial region of an upper surface of the first conductivity type semiconductor layer, a second conductivity type semiconductor layer disposed on the active layer, and the first conductivity type semiconductor layer. The first light emitting stack (1010) may be disposed on a growth substrate (1001), and the growth substrate (1001) may be removed.

The light emitting device (120″) may include an adhesive layer (1002) for adhering the first light emitting stack (1010) and the second light emitting stack (1020) between the first light emitting stack (1010) and the second light emitting stack (1020), and an adhesive layer (1004) for adhering the second light emitting stack (1020) and the third light emitting stack (1030) between the second light emitting stack (1020) and the third light emitting stack (1030).

In addition, the light emitting device (120″) may include an insulation layer (1006) covering the first conductivity type semiconductor layer, the active layer, and the second conductivity type semiconductor layer. The insulation layer (1006) may be an insulation layer covering the first light emitting stack (1010), the second light emitting stack (1020), and the third light emitting stack (1030). The insulation layer may include a single layer or a plurality of layers.

The light emitting device (120″) may include a common electrode pad (PD1) commonly connected to the first to third light emitting stacks (1010, 1020, 1030), and individual electrode pads (PD1, PD2, PD3, PD4) respectively connected to the first to third light emitting stacks (1010, 1020, 1030).

The common electrode pad (PD1) may be connected to the first conductivity type semiconductor layer of the first to third light emitting stacks (1010, 1020, 1030). The individual electrode pads (PD2, PD3, PD4) may be respectively connected to the second conductivity type semiconductor layer of the first to third light emitting stacks (1010, 1020, 1030).

The insulation layer (1006) may include a sixth opening hole (OP6) exposing the first conductivity type semiconductor layer of the first light emitting stack (1010) and a fourth opening hole (OP4) exposing the second conductivity type semiconductor layer of the first light emitting stack (1010). The common electrode pad (PD1) may be a first electrode pad connected to the first conductivity type semiconductor layer of the first light emitting stack (1010) through the sixth opening hole (OP6). In addition, the individual electrode pad (PD4) may be a second electrode pad connected to the second conductivity type semiconductor layer of the first light emitting stack (1010) through the fourth opening hole (OP4). For the first light emitting stack (1010), the sixth opening hole (OP6) may correspond to a first opening for a first electrode pad, and the fourth opening hole (OP4) may correspond to a second opening for a second electrode pad.

Similarly, the insulation layer (1006) may include a fifth opening hole (OP5) exposing the first conductivity type semiconductor layer of the second light emitting stack (1020) and a second opening hole (OP2) exposing the second conductivity type semiconductor layer of the second light emitting stack (1020). The common electrode pad (PD1) may be a first electrode pad connected to the first conductivity type semiconductor layer of the second light emitting stack (1020) through the fifth opening hole (OP5). In addition, the individual electrode pad (PD2) may be a second electrode pad connected to the second conductivity type semiconductor layer of the second light emitting stack (1020) through the second opening hole (OP2). For the second light emitting stack (1020), the fifth opening hole (OP5) may correspond to a first opening for a first electrode pad, and the second opening hole (OP2) may correspond to a second opening for a second electrode pad.

Likewise, the insulation layer (1006) may include a first opening hole (OP1) exposing the first conductivity type semiconductor layer of the third light emitting stack (1030) and a third opening hole (OP3) exposing the second conductivity type semiconductor layer of the third light emitting stack (1030). The common electrode pad (PD1) may be a first electrode pad connected to the first conductivity type semiconductor layer of the third light emitting stack (1030) through the first opening hole (OP1). In addition, the individual electrode pad (PD3) may be a second electrode pad connected to the second conductivity type semiconductor layer of the third light emitting stack (1030) through the third opening hole (OP3). For the third light emitting stack (1030), the first opening hole (OP1) may correspond to a first opening for a first electrode pad, and the third opening hole (OP3) may correspond to a second opening for a second electrode pad.

Referring to FIG. 12a, a diameter (N2) of the second opening hole (OP3) corresponding to the second opening for the third light emitting stack (1030) may be 15% or more of a diameter (N1) of the individual electrode pad (PD3) corresponding to the second electrode pad. By sufficiently securing the diameter of the second opening, it is possible to prevent the individual electrode pad (PD3) from being detached from the second opening. Similarly, a diameter (N4) of the second opening hole (OP2) corresponding to the second opening for the second light emitting stack (120) may be 15% or more of a diameter (N3) of the individual electrode pad (PD2) corresponding to the second electrode pad. In addition, the area of the third opening hole (OP3) and the second opening hole (OP2) may be 25% or more of the area of the individual electrode pads (PD3, PD2), respectively.

Likewise, referring to FIG. 12b, a diameter (N6) of the fourth opening hole (OP4) corresponding to the second opening for the first light emitting stack (1030) may be 15% or more of a diameter (N5) of the individual electrode pad (PD4) corresponding to the second electrode pad. By sufficiently securing the diameter of the second opening, it is possible to prevent the individual electrode pad (PD4) from being detached from the second opening. Similarly, a diameter (N9) of the sixth opening hole (OP6) corresponding to the first opening for the first light emitting stack (1030) may be 15% or more of a diameter (N7) of the common electrode pad (PD1) corresponding to the first electrode pad. A diameter (N8) of the fifth opening hole (OP5) corresponding to the first opening for the second light emitting stack (1020) may be 15% or more of a diameter (N7) of the common electrode pad (PD1) corresponding to the first electrode pad. A diameter (N10) of the first opening hole (OP1) corresponding to the first opening for the third light emitting stack (1030) may be 15% or more of a diameter (N7) of the common electrode pad (PD1) corresponding to the first electrode pad. In addition, the area of the first, fourth, fifth, and sixth opening holes (OP1, OP4, OP5, OP6) may be 25% or more of the area of the individual electrode pad (PD1) or the individual electrode pad (PD4), respectively.

However, the light emitting devices (120, 120′, 120″) of the present invention described above are not limited to a specific structure, and may be implemented by being modified into various structures. The light emitting devices (120, 120′, 120″) can be modified into various structures such as a flip-chip type, a vertical type, a lateral type, and others. In addition, depending on the shape of the light emitting devices (120, 120′, 120″), a growth substrate may be omitted.

Again, referring to FIGS. 1 and 2, the interval (S3) between the plurality of IC drivers (130) may be 2 times or more of side lengths (L3, L4) of the IC driver (130). The plurality of IC drivers (130) may be spaced apart from each other in the first direction or the second direction. The interval (S3) between adjacent IC drivers (130) in the first direction or the second direction may be 1.2 mm or more. Preferably, the interval (S3) may be 1.23 mm or more. By arranging the IC drivers (130) at a sufficiently wide interval, it is possible to prevent problems such as interference, falling off, or damage between the IC drivers (130) when the light emitting module (100) is bent. By arranging fewer IC drivers (130), which are relatively large in size, than the light emitting devices (120, 120′, 120″), the flexibility of the light emitting module (100) can be maintained.

Meanwhile, the interval (M) between the IC driver (130) and an adjacent light emitting device (120, 120′, 120″) may be longer than a side length of the IC driver (130). For example, it may be 700 μm or more. More preferably, the interval (M) may be 800 μm or more. Through this, it is possible to prevent problems such as interference, falling off, or damage between the IC driver (130) and the light emitting device (120, 120′, 120″).

The electrode pads (PD, PD1, PD2, PD3, PD4) of the light emitting devices (120, 120′, 120″) may be electrically connected to a metal pattern disposed on one surface of the substrate (110). Referring to FIG. 2, the metal pattern may include a common interconnection (140) commonly connected to the plurality of light emitting devices (120, 120′, 120″), and a plurality of auxiliary interconnections (161, 162, 163, 164) respectively connected to the plurality of light emitting devices (120, 120′, 120″). At this time, the bending radius of the metal pattern may be larger than the bending radius of the substrate (100).

The common interconnection (140) may be disposed outside of an edge of the substrate (100). In more detail, the common interconnection (140) may extend along the first direction (or second direction) outside of an edge of one surface of the substrate (100). Through this, the bending radius of the light emitting module (100) can be adjusted by arranging the common interconnection (140), which has a relatively large bending radius, on the outside. Accordingly, it is possible to prevent problems such as interference, falling off, or damage between devices when the light emitting module (100) is bent.

The common interconnection (140) may be provided in a plurality. When the common interconnection (140) is formed to extend along the first direction, the plurality of common interconnections (140) may be spaced apart from one another along the second direction. The light emitting device (120, 120′, 120″) and the IC driver (130) may be disposed between the common interconnections (140). A distance (K) from the IC driver (130) to the common interconnection (140) may be 1.5 to 2 times or less of a side length (L3, L4) of the IC driver (130). For example, when the side lengths (L3, L4) of the IC driver (130) are 650 μm, the distance (K) to the common interconnection (140) may be 1.7 mm or less. For example, the distance (K) may be 1.6 mm or less. Through this, it is possible to reduce interference of electrical signals in the common interconnection (140) while preventing problems such as interference, falling off, or damage between devices when the light emitting module (100) is bent.

In addition, the auxiliary interconnections (161, 162, 163, 164) are interconnections disposed adjacent to the light emitting device (120, 120′, 120″), and by making their thickness small within the light emitting unit (U), the influence on the bending radius of the light emitting module (100) can be minimized.

Next, FIG. 13 illustrates a light emitting module (500) according to yet another embodiment of the present invention. The substrate (510) of the light emitting module (500) may be a flexible substrate. The light emitting module (500) may be configured to be identical or similar to the light emitting module (100) of FIGS. 1 and 2, except for the shape of the metal pattern on the substrate (510) and the arrangement of the light emitting devices (520) and the IC drivers (530), so descriptions of overlapping configurations are omitted. E in FIG. 13 is a metal pattern, and it may be configured to be identical or similar to the metal pattern in FIG. 2, so a detailed description is omitted.

In FIG. 13, the separation interval (S1) between adjacent light emitting devices (520) may be greater than or equal to the thickness of the light emitting device (520).

Next, FIG. 14 illustrates a light emitting module (600) according to yet another embodiment of the present invention. The substrate (610) of the light emitting module (600) may be a flexible substrate. The light emitting module (600) may further include a plurality of IC drivers disposed on one surface of the substrate (610). The light emitting module (600) may be configured to be identical or similar to the light emitting module (100) of FIGS. 1 and 2, except for the shape of the metal pattern on the substrate (610) and the arrangement of the light emitting devices (620), so descriptions of overlapping configurations are omitted. E in FIG. 14 is a metal pattern, and it may be configured to be identical or similar to the metal pattern in FIG. 2, so a detailed description is omitted.

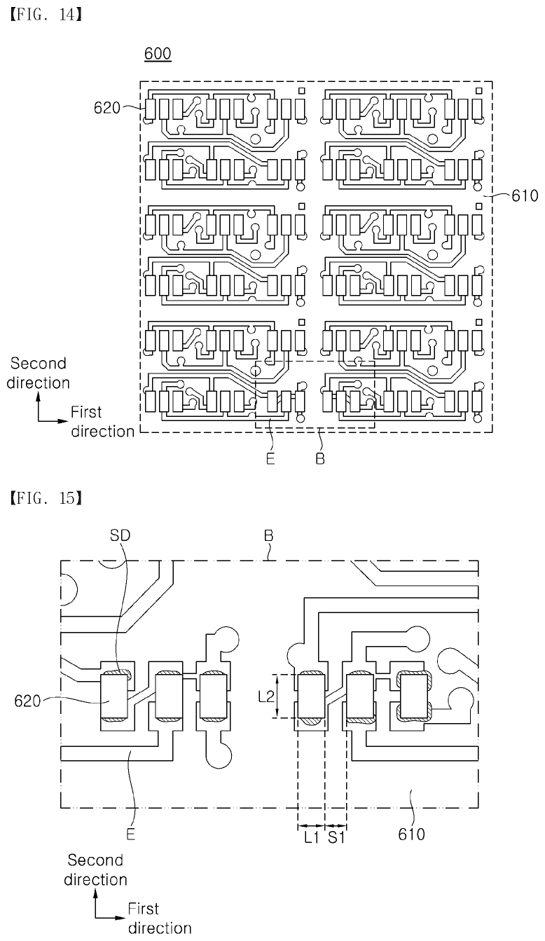

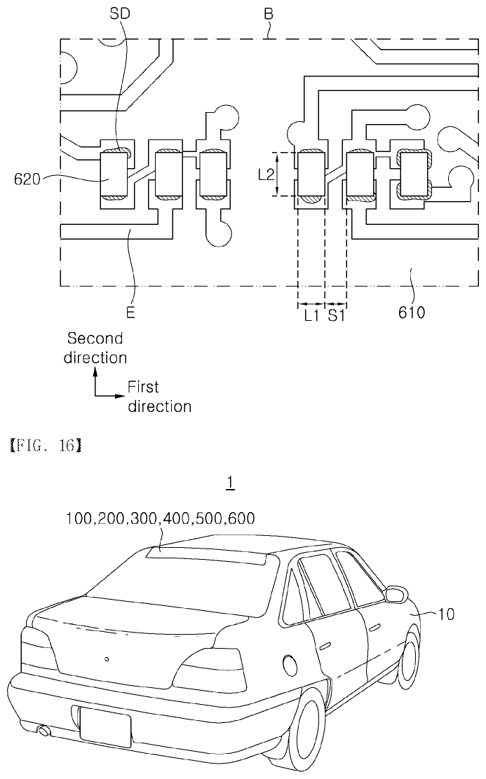

FIG. 15 is an enlarged view showing portion B of FIG. 14, illustrating the light emitting devices (620) disposed on the substrate (610) and the solder (SD) for mounting the light emitting devices (620) on the metal pattern (E). By sufficiently maintaining the separation interval (S1) between the light emitting devices (620) and by sufficiently maintaining the interval between the electrode pads (PD) of adjacent light emitting devices (620), mutual interference can be prevented when the substrate (610) is bent. In addition, by configuring the area of the solder (SD) to be about 30% of the area (L1*L2) of the light emitting device (620), damage such as falling off or cracking of the solder (SD) can be prevented when the substrate (610) is bent.

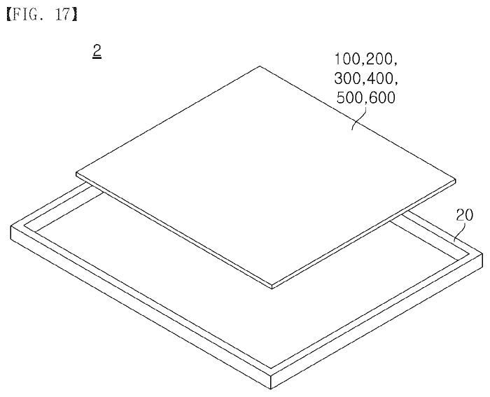

Referring to FIG. 16, a light emitting system (1) including the light emitting modules (100, 200, 300, 400, 500, 600) according to an embodiment of the present invention will be described. For example, the light emitting system (1) may be configured as a truck, passenger car, bus, or others. Such a light emitting system (1) may include a body (10) and the light emitting modules (100, 200, 300, 400, 500, 600).

The body (10) may provide the appearance of the light emitting system (1). The body (10) may be configured to be movable on the road. The light emitting modules (100, 200, 300, 400, 500, 600) may be installed on the body (10).

In addition, the body (10) may include a power supply apparatus for supplying power to the light emitting modules (100, 200, 300, 400, 500, 600). The light emitting modules (100, 200, 300, 400, 500, 600) may generate light. For example, the light emitting modules (100, 200, 300, 400, 500, 600) may display characters, symbols, and images.

In addition, the light emitting modules (100, 200, 300, 400, 500, 600) may be configured as a vehicle window, front glass, rear glass, tail light (rear lamp, tail lamp), headlight, interior light, brake light, grill lamp, or others.

In addition, the light emitting modules (100, 200, 300, 400, 500, 600) may be installed and applied not only in vehicles but also in various places formed of a plate having light transmittance, such as glass or others. In other words, the light emitting modules (100, 200, 300, 400, 500, 600) may also be applied to subway glass, bus glass, airplane windows, building exterior walls, building windows, outdoor advertisements, or others. For example, the light emitting modules (100, 200, 300, 400, 500, 600) may be installed on a subway window to display information such as a subway route map.

Next, referring to FIG. 17, a light emitting system (2) including the light emitting modules (100, 200, 300, 400, 500, 600) according to another embodiment of the present invention will be described. For example, the light emitting system (2) may include the light emitting modules (100, 200, 300, 400, 500, 600). In addition, the light emitting system (2) may be formed transparently. In addition, the light emitting system (2) may be configured as a display apparatus, for example.

The light emitting system (2) may display information, and may function to output various visual contents. In addition, a frame (20) may be provided outside of the light emitting system (2). An electrical interconnection may be added to one region of the frame (20). Through this, the light emitting system (2) may be electrically connected to an external power source, and its operation may be controlled according to an electrical signal. In addition, the light emitting system (2) may be controlled according to an external signal, thereby being driven in various ways.

Moreover, the frame (20) may function to reinforce a strength of the light emitting system (2), and may be formed of a material stronger than the light emitting modules (100, 200, 300, 400, 500, 600). Through this, the frame (20) may also be utilized as a structural support for connecting different light emitting modules (100, 200, 300, 400, 500, 600). Various materials may be used for the frame (20) depending on mechanical strength, processability, or others. For example, the frame (20) may be formed of a metallic material such as aluminum, stainless steel, or copper. In addition to this, the frame (20) may be formed of a polymer material such as polycarbonate, acrylic, polyamide, and ABS, or a material such as carbon fiber reinforced plastic, glass fiber reinforced plastic, and ceramic.

In addition, the frame (20) may be manufactured in a form that surrounds the light emitting modules (100, 200, 300, 400, 500, 600) so as to reinforce the strength of the light emitting system (2), but the inventive concepts are not limited thereto. The frame (20) may be disposed only on one surface of the light emitting modules (100, 200, 300, 400, 500, 600) so as to increase a transparency of the light emitting system (2).

Although the present disclosure has been described above with reference to preferred embodiments, it will be understood by those skilled in the art or having ordinary knowledge in the art that various modifications and changes may be made to the present disclosure without departing from the spirit and technical scope of the present disclosure as set forth in the claims below.

Therefore, the technical scope of the present disclosure should not be limited to the contents described in the detailed description of the specification, but should be defined by the scope of the patent claims.

### DESCRIPTION OF REFERENCE NUMERALS

1, 2: Light emitting system
10: Body
20: Frame
100, 200, 300, 400, 500, 600: Light emitting module
110, 210, 310, 410, 510, 610: Light-transmitting substrate
120, 220, 320, 420, 520, 620: Light emitting device
PD1, PD2, PD3, PD4: Electrode pad
130, 230, 330, 430, 530, 630: IC driver
140: Common interconnection
152, 154: Signal interconnection
161, 162, 163, 164: Auxiliary interconnection
301, 1010: First light emitting stack
302, 1020: Second light emitting stack
303, 1030: Third light emitting stack

1. A light emitting module, comprising:
a substrate; and
a plurality of light emitting devices disposed on the substrate,
wherein an interval between the plurality of light emitting devices is 50 μm or more.

2. The light emitting module of claim 1, wherein the substrate is a light-transmitting substrate,
the light emitting module further comprises a plurality of IC drivers disposed on the substrate for driving the plurality of light emitting devices, and
the interval between the plurality of light emitting devices is 10 times or more of a side length of one of the light emitting devices.

3. The light emitting module of claim 2, wherein an interval between the plurality of IC drivers is 10 times or more of a side length of one of the IC drivers.

4. The light emitting module of claim 2, wherein an area of an arrangement region in which the plurality of light emitting devices and the plurality of IC drivers are disposed among the substrate is 25% or less of a total area of the substrate.

5. The light emitting module of claim 2, further comprising:
a common interconnection disposed on one surface of the substrate and commonly connected to the plurality of light emitting devices; and
a plurality of auxiliary interconnections respectively connected to the plurality of light emitting devices, wherein a thickness of one of the auxiliary interconnections is 0.25 times or less of a side length of one of the light emitting devices.

6. The light emitting module of claim 2, wherein the plurality of light emitting devices are disposed on one surface of the substrate, and the plurality of IC drivers are disposed on another surface of the substrate.

7. The light emitting module of claim 2, wherein at least one of the plurality of light emitting devices is vertically stacked with one of the IC drivers.

8. The light emitting module of claim 2, further comprising a light path control layer disposed on at least a part of a region of one surface of the substrate.

9. The light emitting module of claim 8, wherein the light path control layer includes a cloaking layer to conceal the plurality of light emitting devices and the plurality of IC drivers from being recognized by a naked eye.

10. The light emitting module of claim 2, wherein, when a number of the plurality of IC drivers is X (X is a natural number of 1 or more), a number of the plurality of light emitting devices is X*Y (Y is a natural number of 2 or more).

11. The light emitting module of claim 1, wherein the substrate is a flexible substrate, and an area of solder for mounting a light emitting device of the light emitting devices on the substrate is 25% to 50% of an area of the light emitting device.

12. The light emitting module of claim 11, wherein the thickness of the solder is 5 μm or more.

13. The light emitting module of claim 11,
wherein one of the light emitting devices includes a semiconductor layer including a first conductivity type semiconductor layer, a second conductivity type semiconductor layer, and an active layer, and a plurality of electrode pads connected to the semiconductor layer.

14. The light emitting module of claim 13, wherein a separation interval between the electrode pads is 70 μm or more between adjacent two light emitting devices.

15. The light emitting module of claim 13, wherein a separation interval between the plurality of electrode pads of one of the light emitting devices is 50 μm or more.

16. The light emitting module of claim 11, wherein one of the light emitting devices includes a plurality of light emitting stacks that emit light of different peak wavelengths and are vertically stacked, a common electrode pad commonly connected to the plurality of light emitting stacks, and a plurality of individual electrode pads respectively connected to the plurality of light emitting stacks.

17. The light emitting module of claim 16,
wherein the light emitting stack includes a first conductivity type semiconductor layer, an active layer disposed in a partial region of an upper surface of the first conductivity type semiconductor layer, a second conductivity type semiconductor layer disposed on the active layer, an insulation layer covering the first conductivity type semiconductor layer, the active layer, and the second conductivity type semiconductor layer, a first electrode pad disposed on the insulation layer and connected to the first conductivity type semiconductor layer exposed through a first opening of the insulation layer, and a second electrode pad disposed on the insulation layer and connected to the second conductivity type semiconductor layer exposed through a second opening of the insulation layer.

18. The light emitting module of claim 17, wherein a diameter of the first opening and the second opening is 15% or more of a diameter of the first electrode pad and the second electrode pad, respectively.

19. A light emitting module, comprising:
a substrate;
a plurality of light emitting devices disposed on the substrate; and
a plurality of IC drivers disposed on the substrate to drive the plurality of light emitting devices,
wherein an interval between the plurality of light emitting devices is 10 times or more of a side length of one of the light emitting devices.

20. A light emitting module, comprising:
a substrate; and
a plurality of light emitting devices disposed on the substrate,
wherein one of the light emitting devices includes a semiconductor layer including a first conductivity type semiconductor layer, a second conductivity type semiconductor layer, and an active layer, an insulation layer covering the semiconductor layer, and a plurality of electrode pads connected to the semiconductor layer through an opening of the insulation layer, and
wherein an interval between the electrode pads is 70 μm or more between adjacent two light emitting devices.
